(19) United States
(12) Patent Application Publication
(10) Pub. No.: US 2004/0190322 A1
(43) Pub. Date: Sep. 30, 2004

(54) Circuit and method for reducing the effects of memory imprinting

(76) Inventors: Robert C. Baumann, Dallas, TX (US); John Rodriguez, Richardson, TX (US)

Correspondence Address: TEXAS INSTRUMENTS INCORPORATED, P O BOX 655474, M/S 3999, DALLAS, TX, 75265

(21) Appl. No.: 10/402,708

(22) Filed: Mar. 28, 2003

(51) Int. Cl. G11C 11/22

(52) U.S. Cl. 365/145

(57) ABSTRACT

A memory circuit and method for reducing the effects of memory imprinting is disclosed. The circuit includes a plurality 1500 of nonvolatile memory cells for storing data. A control terminal 1520 is arranged to receive a control signal INV. A data circuit 1510, 1512 is coupled to the control terminal and arranged to invert the data in the nonvolatile memory cells in response to the control signal. Repeated inversion of the data state of the nonvolatile memory cells reduces the effects of memory imprinting.

### FIELD OF THE INVENTION

This invention generally relates to electronic circuits, and more specifically to nonvolatile semiconductor integrated circuits.

### BACKGROUND OF THE INVENTION

Nonvolatile memory circuits such as electrically erasable programmable read only memories (EEPROM) and Flash EEPROMs have been widely used for several decades in various circuit applications including computer memory, automotive applications, and video games. Many new applications, however, require the access time and packing density of previous generation nonvolatile memories in addition to low power consumption for battery powered circuits. One nonvolatile memory technology that is particularly attractive for these low power applications is the ferroelectric memory cell. A major advantage of these ferroelectric memory cells is that they require approximately three orders of magnitude less energy for write operations than previous generation floating gate memories. Furthermore, they do not require high voltage power supplies for programming and erasing charge stored on a floating gate. Thus, circuit complexity is reduced and reliability increased.

The term ferroelectric is something of a misnomer, since present ferroelectric capacitors contain no ferrous material. Typical ferroelectric capacitors include a dielectric of ferroelectric material formed between two closely-spaced conducting plates. One well-established family of ferroelectric materials known as perovskites has a general formula ABO₃. This family includes Lead Zirconate Titanate (PZT) having a formula Pb(ZrₓTi₁₋ₓ)O₃. This material is a dielectric with a desirable characteristic that a suitable electric field will displace a central atom of the lattice. This displaced central atom, either Titanium or Zirconium, remains displaced after the electric field is removed, thereby storing a net charge. Another family of ferroelectric materials is Strontium Bismuth Titanate (SBT) having a formula SbBi₂Ta₂O₉. SBT has several advantages over PZT. However, both ferroelectric materials suffer from fatigue and imprint. Fatigue is characterized by a gradual decrease in net stored charge with repeated cycling of a ferroelectric capacitor. Imprint is a tendency to prefer one state over another if the ferroelectric capacitor remains in that state for a long time as will be discussed in detail.

A typical one-transistor, one-capacitor (1T1C) ferroelectric memory cell of the prior art is illustrated at FIG. 1. The ferroelectric memory cell is similar to a 1T1C dynamic random access memory (DRAM) cell except for ferroelectric capacitor 100. The ferroelectric capacitor 100 is connected to plateline 110 and access transistor 102. Access transistor 102 has a current path connected between bitline 108 and ferroelectric capacitor 100. A control gate of access transistor 102 is connected to wordline 106 to control reading and writing of data to the ferroelectric memory cell. This data is stored as a polarized charge corresponding to cell voltage Vc. Parasitic capacitance of bitline BL is represented by capacitor C_{BL} 104.

Referring to FIG. 2, there is a hysteresis curve corresponding to the ferroelectric capacitor 100. The hysteresis curve includes net charge Q or polarization along the vertical axis and voltage along the horizontal axis. By convention, the polarity of cell voltage is defined as shown in FIG. 1. A stored “0”, therefore, is characterized by a positive voltage at the plateline terminal with respect to the access transistor terminal. A stored “1” is characterized by a negative voltage at the plateline terminal with respect to the access transistor terminal. A “0” is stored in a write operation by applying a voltage Vmax across the ferroelectric capacitor. This stores a saturation charge Qs in the ferroelectric capacitor. The ferroelectric capacitor, however, includes a linear component in parallel with a switching component. When the electric field is removed, therefore, the linear component discharges and only the residual charge Qr remains in the switching component. The stored “0” is rewritten as a “1” by applying −Vmax to the ferroelectric capacitor. This charges the linear and switching components of the ferroelectric capacitor to a saturation charge of −Qs. The stored charge reverts to −Qr when the electric field is removed. Finally, coercive points V_{C} and −V_{C} are minimum voltages on the hysteresis curve that will degrade a stored data state. For example, application of V_{C} across a ferroelectric capacitor will degrade a stored “1” even though it is not sufficient to store a “0”. Thus, it is particularly important to avoid voltages near these coercive points unless the ferroelectric capacitor is being accessed.

Referring to FIG. 3, there is illustrated a typical write sequence for a ferroelectric memory cell as in FIG. 1. Initially, the bitline (BL), wordline (WL), and plateline (PL) are all low. The upper row of hysteresis curves illustrates a write “1” and the lower row represents a write “0”. Either a “1” or “0” is initially stored in each exemplary memory cell. The write “1” is performed when the bitline BL and wordline WL are high and the plateline PL is low. This places a negative voltage across the ferroelectric capacitor and charges it to −Qs. When plateline PL goes high, the voltage across the ferroelectric capacitor is 0 V, and the stored charge reverts to −Qr. At the end of the write cycle, both bitline BL and plateline PL go low and stored charge −Qr remains on the ferroelectric capacitor. Alternatively, the write “0” occurs when bitline BL remains low and plateline PL goes high. This places a positive voltage across the ferroelectric capacitor and charges it to Qs representing a stored “1”. When plateline PL goes low, the voltage across the ferroelectric capacitor is 0 V, and the stored charge reverts to Qr representing a stored “0”.

A read operation is illustrated at FIG. 4 for the ferroelectric memory cell at FIG. 1. The upper row of hysteresis curves illustrates a read “0”. The lower row of hysteresis curves illustrates a read “1”. Wordline WL and plateline PL are initially low. Bitlines BL are precharged low. At time Δt₀ precharge signal PRE goes low, permitting the bitlines BL to float. At time Δt₁ both wordline WL and plateline PL go high, thereby permitting each memory cell to share charge with a respective bitline. A stored “1” will share more charge with parasitic bitline capacitance C_{BL} and produce a greater bitline voltage than the stored “0” as shown. A reference voltage (not shown) is produced at each complementary bitline of an accessed bitline. This reference voltage is between the “1” and “0” voltages. Sense amplifiers are activated at the time boundary between Δt₁ and Δt₂. When respective bitline voltages are fully amplified in time Δt₂, the read “0” curve cell charge has increased from Qr to Qs. By way of comparison, the read “1” data state has changed from a stored “1” to a stored “0”. Thus, the read “0” operation is nondestructive, but the read “1” operation is destructive. At time Δt₃, plateline PL goes low and applies −Vmax to the read “1” cell, thereby storing −Qs. At the same time, zero voltage is applied to the read “0” cell and charge Qr is restored. At the end of time Δt₃, signal PRE goes high and precharges both bitlines BL return to zero volts or ground. Thus, zero volts is applied to the read “1” cell and −Qr is restored.

The difference voltage presented to each sense amplifier during time Δt₂ is critical to correct operation of the ferroelectric memory. This voltage is a difference between the reference voltage and one of the read “1” and read “0” bitline voltages after charge sharing with the respective bitline capacitance. This difference voltage is further reduced by noise in the memory device and fatigue and imprint of the ferroelectric memory cell. For example, if the hysteresis curve shifts to the left or right due to imprint, residual charge Qr and the resulting difference voltage is reduced for a data state.

### SUMMARY OF THE INVENTION

In accordance with a preferred embodiment of the invention, there is disclosed a memory circuit for reducing the effects of memory imprinting. The circuit comprises a plurality of memory cells for storing data. A control terminal is arranged to receive a control signal. A data circuit is coupled to the control terminal. The data circuit is arranged to invert the data in the nonvolatile memory cells in response to the control signal. This data inversion advantageously avoids prolonged storage of a single data state in the nonvolatile memory cells. Thus, cell imprint is minimized.

### BRIEF DESCRIPTION OF THE DRAWINGS

The foregoing features of the present invention may be more fully understood from the following detailed description, read in conjunction with the accompanying drawings, wherein:

FIG. 1 is a circuit diagram of a ferroelectric memory cell of the prior art;

FIG. 2 is a hysteresis curve of the ferroelectric capacitor 100 of FIG. 1;

FIG. 3 is a timing diagram showing a write operation to the ferroelectric memory cell of FIG. 1;

FIG. 4 is a timing diagram showing a read operation from the ferroelectric memory cell of FIG. 1;

FIG. 5 is a simplified test circuit to measure the hysteresis curve of a ferroelectric capacitor;

FIG. 6 is a waveform diagram showing a Positive-Up-Negative-Down (PUND) measurement sequence;

FIG. 7 is a diagram showing a temperature accelerated bake sequence together with the PUND measurement sequence of test capacitors A and B;

FIG. 8 is a table showing results of the bake and measurement sequence of FIG. 7;

FIG. 9 is a hysteresis curve of a test capacitor prior to temperature accelerated bake;

FIG. 10 is a diagram of hysteresis curves of a test capacitor with a stored “1” before and after temperature accelerated bake;

FIG. 11 is a diagram of hysteresis curves of a test capacitor with a stored “0” before and after temperature accelerated bake;

FIG. 12 is a diagram showing signal margin degradation for a test capacitor with a stored “0” as a function of temperature accelerated bake time;

FIG. 13 is a diagram showing signal margin degradation for a test capacitor with a stored “1” as a function of temperature accelerated bake time;

FIG. 14 is a diagram showing signal margin degradation for test capacitors with same state (SS) data and opposite state (OS) data as a function of temperature accelerated bake time;

FIG. 15 is a circuit diagram showing an embodiment of a data inversion circuit of the present invention;

FIG. 16 is a circuit diagram of the counter latch of FIG. 15;

FIG. 17 is a circuit diagram of the status latch of FIG. 15; and

FIG. 18 is a circuit diagram of the data path inverting circuit of FIG. 15.

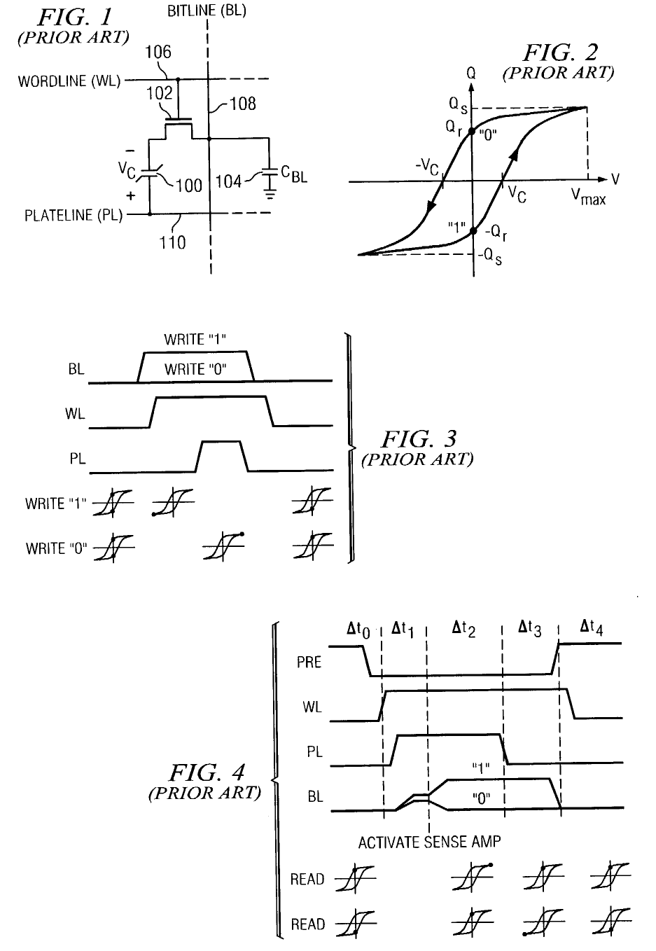

### DETAILED DESCRIPTION OF PREFERRED EMBODIMENTS

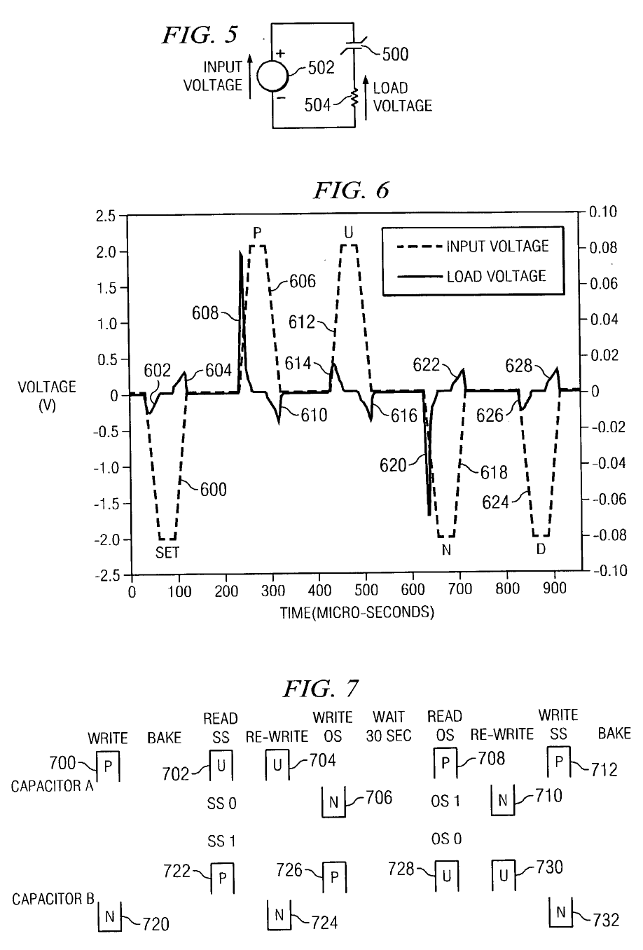

Ferroelectric test capacitors were fabricated to determine the effect of data imprint on signal margin as a function of time. These test capacitors were measured as shown in the simplified circuit diagram of FIG. 5. A pulse waveform from voltage source 502 was applied to ferroelectric capacitor 500. Dynamic voltage across load resistor 504, corresponding to rising and falling edges of the pulse waveform, provides charge from linear and switching components of the ferroelectric capacitor. By way of example, test waveforms are illustrated at FIG. 6. Capacitor 500 initially stores a data “1”. A negative SET pulse, corresponding to a positive bitline with respect to a grounded plateline, is applied to capacitor 500. Since respective magnitudes of leading edge 602 and trailing edge 604 dynamic voltage waveforms have the same magnitude, the switching component of capacitor 500 remains unchanged in a stored “1” state. Only the linear component of capacitor 500 is charged and discharged. Next, pulse P 606, corresponding to a positive plateline with respect to a grounded bitline, is applied to capacitor 500. The magnitude of the leading edge voltage pulse 608 indicates a change in the switching component of capacitor 500 to a data “0” as well as the linear component. The magnitude of the trailing edge voltage pulse 610 is due to the linear component of capacitor 500. The switching component remains unchanged in a data “0” state. A U pulse 612 is applied with the same polarity and magnitude as the preceding P pulse 606. Leading 614 and trailing 616 edge waveforms show no change in the switching component of capacitor 500. Only the linear component charges and discharges. Since resistor 504 is linear, current through resistor 504 is proportional to each of voltage waveforms 608, 610, 614, and 616. Moreover, the total charge difference of a change from a data “1” state to a data “0” state of capacitor 500 is simply an integral of the difference between dynamic current from pulse P (608, 610) and pulse U (614, 616).

An N pulse 618 is applied to capacitor 500 to change the switching component back to a data “1” state. This corresponds to a positive bitline with respect to a grounded plateline. Again, the magnitude of leading edge pulse 620 indicates a change in the switching component of capacitor 500. An identical D pulse 624 follows the N pulse and indicates no change in the switching component of capacitor 500. Total charge difference of a change from a data “0” state to a data “1” state of capacitor 500, therefore, is an integral over time of the difference between current of pulse N (620, 622) and pulse D (626, 628).

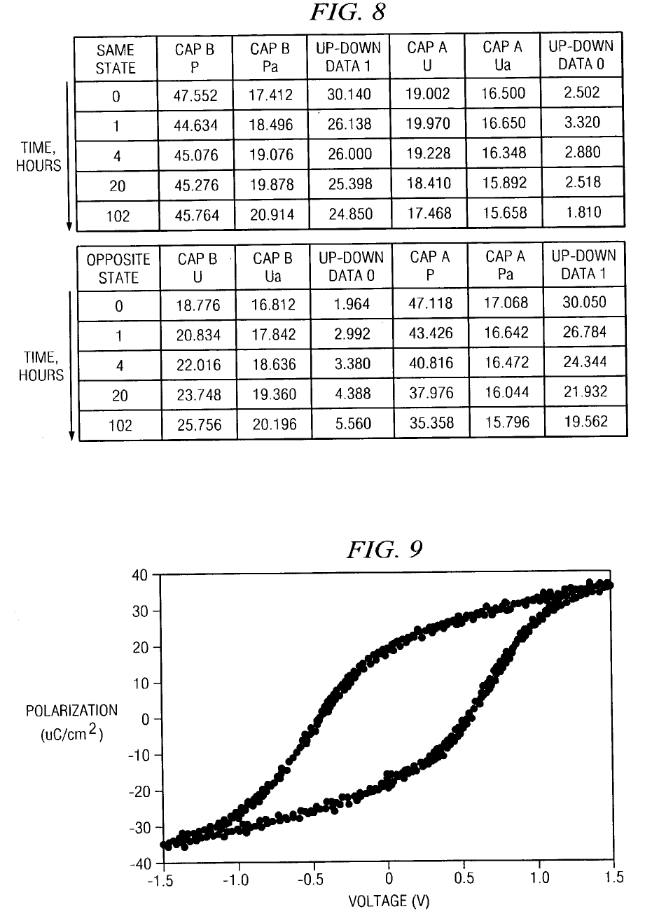

Referring now to FIG. 7, the previously described PUND test is applied to ferroelectric capacitors A and B at periodic read points shown at FIG. 8 of a temperature accelerated bake sequence. Capacitor A is initialized in a data “0” state by pulse P 700 and baked at 150° C. until the first read point at 1 hour. Pulse U 702 is then applied to read same state data “0”. Rewrite pulse U 704 is then applied to rewrite the data “0” even though the read was nondestructive. Next, pulse N 706 is applied to write opposite data “1” to capacitor A. After fixed delay time of preferably a few seconds to 30 seconds, pulse P 708 is applied to read the opposite data “1”. Since the data “1” read is destructive, the opposite data “1” is then rewritten by pulse N 710. Finally, pulse P 712 writes a same state data “0” and the 150° C. bake sequence continues to the next read point. The sequence then repeats starting with pulse U 702.

The PUND test for capacitor B is different from capacitor A, since capacitor B maintains a data “1” through the bake sequence. A data “1” is initially written to capacitor B by pulse N 720. Pulse P 722 performs a destructive read of the same state data “1”. The data “1” is then rewritten by pulse N 724. Pulse P 726 then rewrites an opposite state data “0”. After 30 seconds pulse U 728 reads the opposite state data “0”. The data “0” is rewritten by pulse U 730. Finally, pulse N 732 writes the same state date “1”, and the 150° C. bake sequence resumes until the next read point. The sequence then repeats with pulse P 722.

Tabulated data for this test sequence is shown at each read point at FIG. 8 in units of μC/cm². Columns P and Pa refer to charge per unit area at the leading and trailing edges of a P pulse, respectively. Likewise, columns U and Ua refer to charge per unit area at the leading and trailing edges of a U pulse, respectively. For example, pulse U 702 applied to capacitor A at the 1 hour read point conducted a total charge of 19.97 μC/cm² at the leading edge and 16.65 μC/cm² at the trailing edge. This is similar to leading and trailing edge pulses 614 and 616, respectively, at FIG. 6, where a same state data “0” is read. By way of comparison, when pulse P 708 is applied to capacitor A to read the opposite state data “1” at the 1 hour read point, total charge at the leading edge is 43.426 μC/cm² followed by 16.642 μC/cm² at the trailing edge. This corresponds to leading and trailing edge pulses 608 and 610 of FIG. 6. Each entry of the Up-Down data columns is a difference between two data entries to the immediate left. For example, Up-Down Data 0 for a same state read of capacitor A at the 1 hour read point is 3.32 μC/cm², a difference between 19.97 μC/cm² and 16.65 μC/cm².

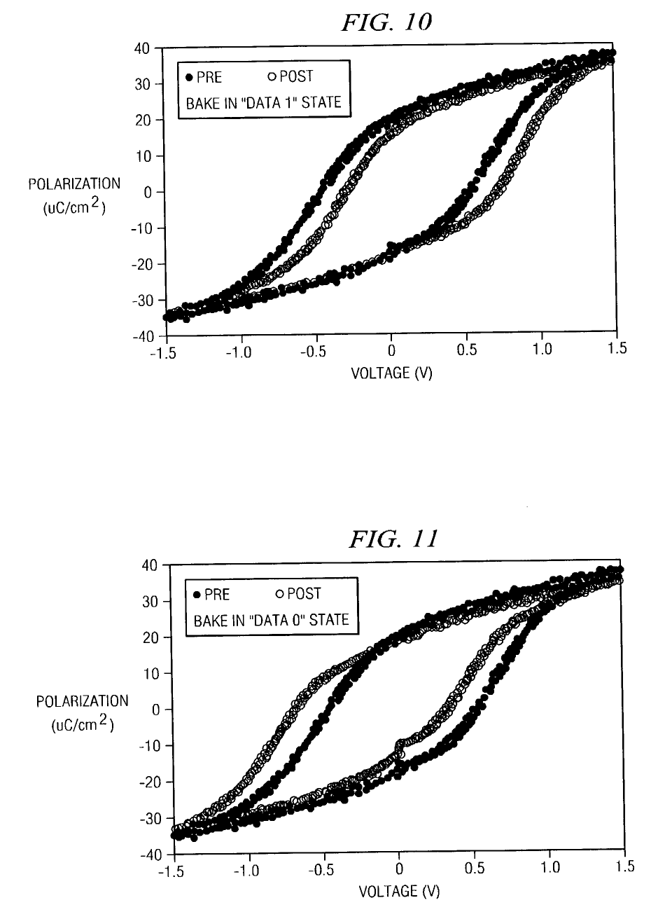

The significance of these data is illustrated by a change in the hysteresis curve of the ferroelectric capacitor. The curve of FIG. 9 is a taken prior to the accelerated bake sequence. The vertical axis shows polarization or charge of in units of μC/cm². The horizontal axis is shows voltage across the ferroelectric capacitor. Residual charge +Qr and −Qr are both approximately +/−20 μC/cm². FIG. 10 is a post bake hysteresis curve of capacitor B after 102 hours at 150° C. in data “1” state. The post bake hysteresis curve is superimposed on the pre bake curve for comparison. The data “1” residual charge −Qr remains about −20 μC/cm². This indicates there is little change in the data “1” signal. The data “0” residual charge +Qr, however, has degraded to less than 15 μC/cm². Thus, the accelerated bake sequence in a data “1” state has significantly reduced the ability of ferroelectric capacitor B to store a data “0”. The curve at FIG. 11 shows a post bake hysteresis curve of capacitor A after 102 hours at 150° C. in data “0” state. The post bake hysteresis curve is superimposed on the pre bake curve for comparison. The data “0” residual charge Qr is slightly degraded to less than 20 μC/cm². This indicates there a slight change in the data “0” signal. The data “1” residual charge −Qr, however, has degraded to about −12 μC/cm². Thus, the accelerated bake sequence in a data “0” state has significantly reduced the ability of ferroelectric capacitor A to store a data “1”.

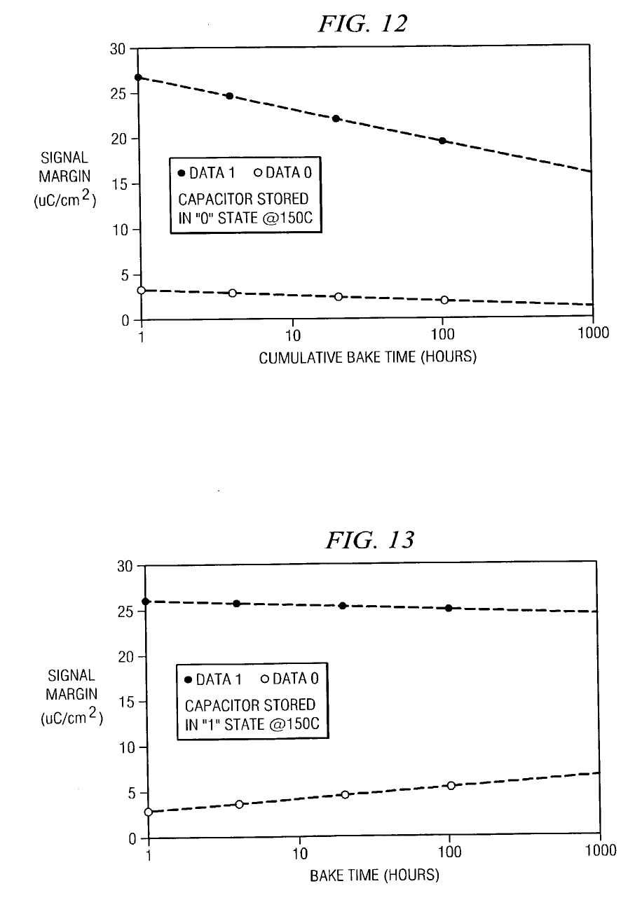

Referring now to FIG. 12, there is a plot of degraded signal margin for capacitor A as a function of cumulative bake time. The data “1” curve is a plot of Up-Down Data “1”. The data “0” curve is a plot of Up-Down Data “0”. The Up-Down Data of FIG. 8 is a difference between a sum of switched component charge plus linear component charge (P, U) and linear component charge (Pa, Ua). Thus, the plot is approximately the switched component charge at each of read points 1, 4, 20, and 102 hours. The data “0” charge is only slightly degraded, but the data “1” charge significantly degrades over time. Thus, the ferroelectric capacitor A has become imprinted to store a data “0” state and a degraded data “1” state. Likewise, the curves at FIG. 13 show the switched component charge of capacitor B as a function of cumulative bake time. Here, the data “1” curve is a plot of Up-Down Data “1” and the data “0” curve is a plot of Up-Down Data “0” for capacitor B. The data “1” state is only slightly degraded, however, since capacitor B stored data “1” during bake. The data “0” state shows significantly more degradation. Thus, the ferroelectric capacitor B has become imprinted to store a data “1” state and a degraded data “0” state.

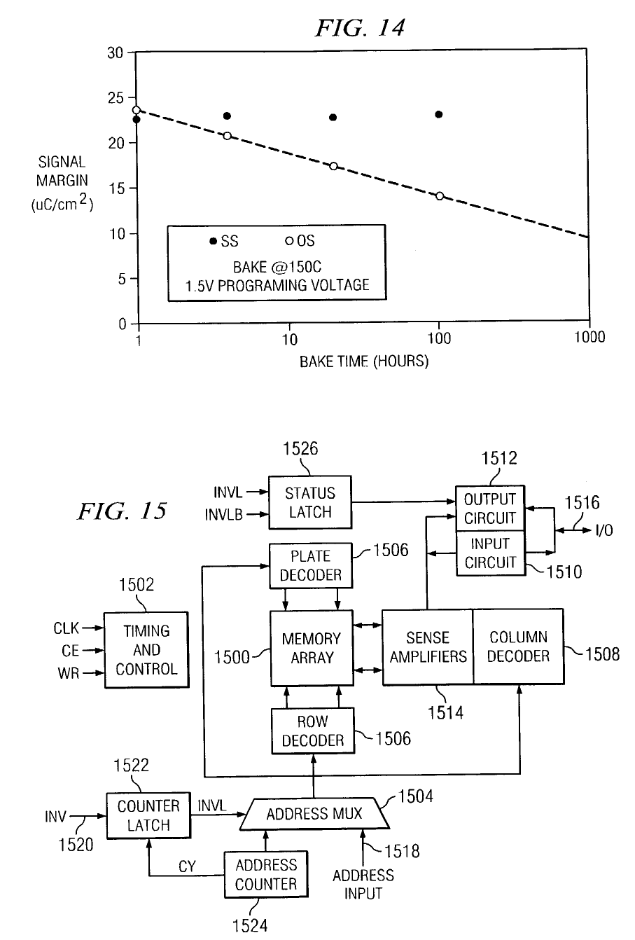

The curves of FIG. 14 show a difference in residual charge between data “1” and data “0” for same state and opposite state data read points. In particular, the same state curve is a difference between the Up-Down Data “1” entries for capacitor B and the Up-Down Data “0” entries for capacitor A (FIG. 8). The same state data remains relatively constant at about 23 μC/cm² for all four read points. Therefore, if either a data “1” or data “0” same state data is applied to one input terminal of a sense amplifier, and an ideal reference voltage having a value exactly between the data “1” and data “0” signals is applied to another terminal of the sense amplifier, the sense amplifier would have about 11.5 μC/cm² available for sensing either data state. This is sufficient, since approximately 5-10 μC/cm² is necessary for accurate sensing of a correct data state. The opposite state curve is a difference between Up-Down Data “1” for capacitor A and Up-Down Data “0” for capacitor B (FIG. 8). This curve is very different from the same state data curve. After the 102 hour bake sequence at 150° C., the difference between data “1” and data “0” residual charge is only 14 μC/cm², a difference between 19.562 μC/cm² and 5.56 μC/cm². Thus, an ideal reference voltage, neglecting noise, could only produce 7 μC/cm² for correctly sensing a data “1” or data “0” state. At this level of stored charge degradation, therefore, data errors are possible. In a practical memory circuit, however, data states of individual memory cells are distributed about their respective mean values. These distributions are due to manufacturing imperfections, memory array layout variations such as metal line resistance, memory cell proximity to noise sources such as the edge of the memory array, and other factors. Thus, data distributions for a weak data “1” and a strong data “0” of a practical memory circuit may be separated, for example, by only 10 μC/cm². A practical reference voltage may only produce 4 μC/cm² for correctly sensing the weak data “1” or strong data “0” state. At this level of stored charge degradation, therefore, data errors are likely.

The bake sequence at 150° C. is accelerated over a 105° C. bake, the high end of the ferroelectric memory operating range, by a factor of 70 to 100 or approximately two orders of magnitude. Thus, a 102 hour bake at 150° C. is approximately equivalent to 7140 to 10200 hours or about 298 to 425 days at 105° C. If the data state of the ferroelectric capacitor is reversed to prevent prolonged storage of a single data state, therefore, ferroelectric capacitor imprinting can be limited to the measured degradation of the previous curves. Thus, data errors can be prevented by limiting time for imprinting. This is highly advantageous, as it eliminates the need for more complex error correction circuitry. Moreover, since charge degradation as a function of time is predictable, the frequency of data inversions may be determined by a timed interrupt from a host processor, an on-chip timer, a power-up signal for the ferroelectric memory, or any other suitable timing signal. Furthermore, such timed data inversions may be optimized to maintain signal margin without signal degradation due to frequent data switching.

Turning now to FIG. 15, there is a circuit of the present invention for inverting data in the ferroelectric memory. The ferroelectric memory includes a memory array 1500 having a plurality of nonvolatile ferroelectric memory cells. A timing and control circuit 1502 receives a clock signal CLK, a chip enable signal CE, and a write signal WR and generates internal signals for operating the ferroelectric memory. In normal operation, the ferroelectric memory receives address input signals at terminals 1518 of address multiplex circuit 1504. Row address bits are routed to row decoder circuit 1506 for selecting a wordline of the memory array. At least one of the row address bits is also applied to the plate decoder circuit 1506 for selecting a corresponding plateline of the memory array. Column address bits are applied to column decoder circuit 1508 for selecting a column of memory cells to couple to the input circuit 1510 during a write operation and to the output circuit 1512 during a read operation. Ferroelectric memory cells along the selected wordline are coupled to their respective bitlines as described at FIG. 1. Sense amplifiers 1514 amplify a difference voltage between a bitline of a selected column and a reference voltage to produce either a data “1” or a data “0” at the output terminals of each sense amplifier. The column decoder circuit 1508 couples a sense amplifier of a selected column to local input/output (LIO, LIOB) lines coupled to input circuit 1510 and output circuit 1512. If write signal WR is high, a write operation is performed and data is driven from the I/O terminal 1516, through the input circuit, and onto the local input/output lines. Alternatively, if write signal WR is low, a read operation is performed and data is driven from the local input/output lines, through the output circuit 1512, and onto the I/O terminal 1516.

A control terminal 1520 is coupled to receive a control signal INV when a data inversion of memory cells in memory array 1500 is required. A counter latch 1522 receives control signal INV and produces a latched inversion signal INVL and a complementary latched inversion signal INVLB. The latched control signal INVL enables address counter, which produces address signals in synchronization with clock signal CLK. The latched control signal INVL also switches address multiplex circuit 1504 to select addresses from the address counter 1524 rather than from the address input terminals 1518. Address counter 1524 begins from an all zero state and sequences through all row, plate, and column addresses of memory array 1500 until it rolls over to an all zero state again. This next all zero state propagates a carry signal CY to reset the counter latch 1522 and terminate the data inversion cycle.

A status latch 1526 is coupled to receive latched control signal INVL and complementary latched control signal INVLB. This status latch stores a present condition of the ferroelectric memory cells in the memory array 1500. In particular, the status latch includes a nonvolatile memory circuit that remembers whether the data in memory array 1500 is stored in a true or complement form. A data circuit 1510, 1512 is coupled to the control terminal 1520 via the status latch. This data circuit is arranged to invert the data in the nonvolatile memory cells of memory array 1500 in response to the control signal INV, as will be explained in detail.

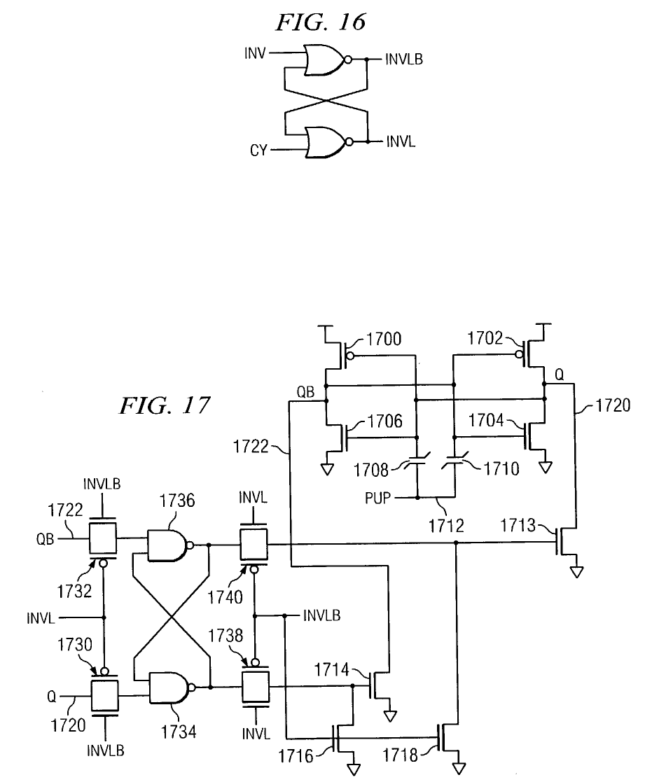

Referring now to FIG. 16 there is a schematic diagram of counter latch 1522 of FIG. 15. The counter latch is an SR flip-flop formed by two cross-coupled NOR gates. In normal operation, control signal INV is low, carry signal CY is low, and latched control signals INVL and INVLB are low and high, respectively. When control signal INV goes high, thereby initiating a data inversion sequence, the SR flip-flop is set, and latched control signals INVL and INVLB go high and low, respectively. They maintain their respective logic states until the data inversion sequence for the memory array 1500 is completed, and address counter 1524 produces a high carry signal CY, indicating counter overflow. This high carry signal CY resets the SR flip-flop and returns latched control signals INVL and INVLB to respective low and high levels. The low level of latched control signal INVL resets address counter 1524, thereby producing a low carry signal CY. The low latched control signal INVL also selects address input terminal 1518 of address multiplexer 1504 for normal operation.

Details of status latch 1526 are shown at FIG. 17. The status latch includes a sense amplifier formed by cross-coupled P-channel transistors 1700 and 1702 and cross-coupled N-channel transistors 1704 and 1706. The sense amplifier is activated by an increasing Vdd supply voltage at the sources of cross-coupled P-channel transistors 1700 and 1702. This increasing Vdd supply voltage also produces a power-up pulse PUP at terminal 1712. Terminal 1712 is a plate terminal for ferroelectric capacitors 1708 and 1710. These ferroelectric capacitors are charged to opposite data states as determined by a previous power-up cycle. The opposite ends of the ferroelectric capacitors are connected to respective input-output terminals 1720 and 1722 of the sense amplifier. In operation, as the Vdd supply voltage increases, the power-up pulse PUP goes high, thereby imposing a differential voltage at input-output terminals 1720 and 1722. This differential voltage sets the sense amplifier in the same logic state as before a previous power-down. After power-up is complete and the Vdd supply voltage has reached an operational level, power-up pulse PUP returns to a low level. In addition to setting logic levels of output signals Q and QB, this power-up sequence also rewrites the stored data in the ferroelectric capacitors 1708 and 1710.

As previously described, in normal circuit operation latched control signals INVL and INVLB remain low and high respectively. Thus, CMOS pass gates 1730 and 1732 are normally on and output signals Q and QB are applied to a latch formed by cross-coupled NAND gates 1734 and 1736. This latch, therefore, holds the state of the sense amplifier output signals Q and QB at power-up. Due to the low and high levels of latched control signals INVL and INVLB, however, CMOS pass gates 1738 and 1740 remain off so that the latched state of output signals Q and QB is isolated from programming transistors 1713 and 1714. Moreover, the high state of latched control signal INVLB turns on N-channel transistors 1716 and 1718, thereby holding the gates of programming transistors 1713 and 1714 low so that they remain off.

When latched control signals INVL and INVLB go high and low, respectively, initiating a data inversion sequence, CMOS pass gates 1730 and 1732 are turned off and CMOS pass gates 1738 and 1740 are turned on. The low level of latched control signal INVLB turns off N-channel transistors 1716 and 1718. The state of the latch formed by cross-coupled NAND gates 1734 and 1736 propagates through CMOS pass gates 1738 and 1740 to programming transistors 1714 and 1713, respectively. Programming transistors 1713 and 1714 override the sense amplifier and cause it to flip to the opposite data state. For example, if output signals Q and QB are initially high and low, respectively, the output signals from NAND gates 1734 and 1736 are low and high, respectively. When latched control signals INVL and INVLB go high and low, respectively, the high level from NAND gate 1736 turns on N-channel programming transistor 1713. N-channel programming transistor 1714 remains off due to the low level output signal from NAND gate 1734. N-channel programming transistor 1713 pulls output signal Q low. The low level of output signal Q turns P-channel transistor 1700 on and N-channel transistor 1706 off, thereby driving output signal QB high.

At the end of the data inversion cycle, latched control signals INVL and INVLB return to their normal low and high levels, respectively. Thus, CMOS pass gates 1730 and 1732 are on, CMOS pass gates 1738 and 1740 are off, and N-channel programming transistors 1713 and 1714 are off. The latch formed by cross-coupled NAND gates 1734 and 1736 is now loaded with the new state of sense amplifier output signals Q and QB.

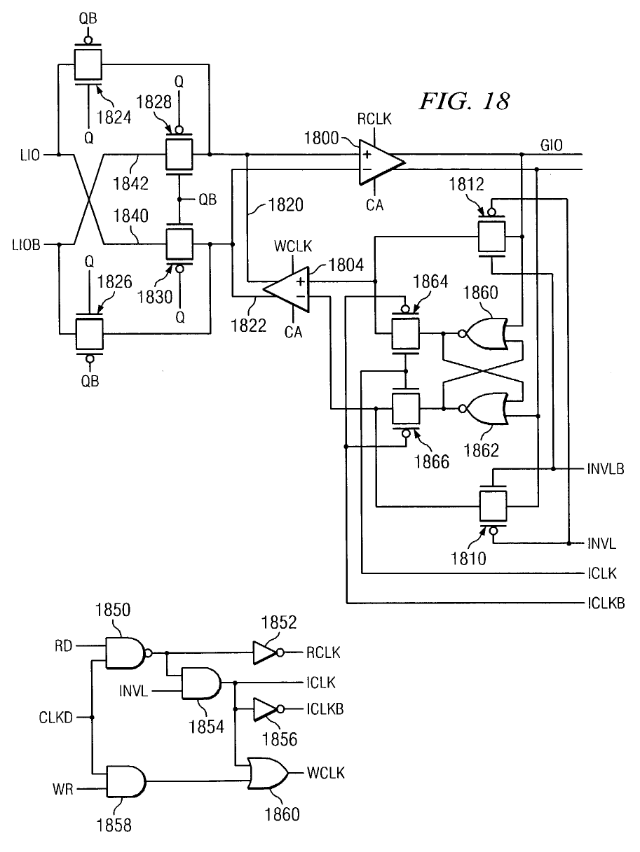

Turning now to FIG. 18, there is a schematic diagram of a data circuit that performs the data inversion of memory array 1500. The data circuit is a combined input-output circuit with common complementary data lines. Local input-output lines LIO and LIOB are coupled to one of sense amplifiers 1514 selected by column decoder circuit 1508. Global input-output lines GIO and GIOB are coupled to receive data from a data input buffer (not shown) and send data to a data output buffer (not shown). Read data amplifier 1800 is coupled to receive data from local input-output lines LIO and LIOB during a read operation, and drive data onto global input-output lines GIO and GIOB in response to read clock signal RCLK and column address signals CA. Write amplifier 1804 is coupled to receive data from global input-output lines GIO and GIOB during a write operation, and drive data onto local input-output lines LIO and LIOB in response to write clock signal WCLK and column address signals CA.

Operation of the data circuit is synchronized by data clock signal CLKD, which is derived from system clock signal CLK. The data circuit also receives read control signal RD and write control signal WR. Only one of read RD and write WR control signals will be active at any time as determined by the write signal WR (FIG. 15) applied to timing and control circuit 1502. Data clock CLKD is applied to NAND gate 1850 together with read signal RD to produce read clock signal RCLK via inverter 1852 in a read operation. Write signal WR is applied to AND gate 1858 together with data clock signal CLKD to produce write clock signal WCLK via OR gate 1860 during a normal write operation. Latched control signal INVL is low during normal read and write operations. Thus, inversion clock signal ICLK remains low and complementary inversion clock signal ICLKB, produced by inverter 1856, remains high.

During a normal write operation, INVL and INVLB respective low and high levels turn on CMOS pass gates 1810 and 1812, which couple global input-output lines GIO and GIOB to the input terminals of write amplifier 1804. Complementary output signals Q and QB from the status latch (FIG. 17) remember whether true or complementary data is stored in memory array 1500 as previously described. If true data is to be stored in memory array 1500, then output signals Q and QB are high and low, respectively. Thus, CMOS pass gates 1824 and 1826 are on and CMOS pass gates 1828 and 1830 are off. Terminals 1820 and 1822 of write amplifier 1804, therefore, are coupled to local input-output signal lines 1840 and 1842, respectively. In this state, a true one applied to data I/O terminal 1516 will be written to memory array 1500 as a true one. Alternatively, if output signals Q and QB are low and high, respectively, then CMOS pass gates 1828 and 1830 are on and CMOS pass gates 1824 and 1826 are off. In this state, terminals 1820 and 1822 of write amplifier 1804 are coupled to local input-output signal lines 1842 and 1840, respectively. Thus, a true one applied to data I/O terminal 1516 will be written to memory array 1500 as a true zero.

During a normal read operation, status latch output signals Q and QB determine which local input-output signal lines are coupled to which read amplifier input terminals. If output signals Q and QB are high and low, respectively, then CMOS pass gates 1824 and 1826 are on and read amplifier 1800 will produce a true one global input-output signal GIO and GIOB in response to a true one in memory array 1500. Alternatively, if output signals Q and QB are low and high, respectively, then CMOS pass gates 1828 and 1830 are on and read amplifier 1800 will produce a true zero global input-output signal GIO and GIOB in response to a true one in memory array 1500. This data inversion, therefore, is transparent to a memory user of host processor. Data written to the memory as a true one or true zero will always be recovered in the same state. Internally, however, a datum may be stored in ferroelectric memory cell as either a true one or a true zero. The stored state depends on the logic state of the status latch 1526 as previously described.

When a data inversion operation is to be performed, latched control signal INVL goes high. Timing and control circuit 1502 produces a high read signal RD and a low write signal WR in response to the high state of INVL. In this state, the output of AND gate 1858 is low. Alternatively, AND gate 1854 is enabled by latched control signal INVL and produces inversion clock signal ICLK, which is a complement of read clock signal RCLK. Inverter 1856 inverts inversion clock signal ICLK to produce complementary inversion clock signal ICLKB. Or gate 1860 produces write clock signal WCLK in response to inversion clock signal ICLK.

The low-to-high transition of latched control signal INVL complements the state of the status latch (FIG. 17) as previously described. The resulting state of output signals Q and QB will determine which pair of CMOS pass gates, 1824 and 1826 or 1828 and 1830, remains on. This has no effect, however, on the data inversion operation. Additionally, CMOS pass gates 1810 and 1812 are off, thereby interrupting the normal data circuit write path. Address counter 1524 produces sequential addresses for every ferroelectric memory cell in memory array 1500. In response to the address sequence, a bit of data is read from memory array 1500 on the local input-output signal lines 1840 and 1842. This data bit is amplified by read amplifier 1800 while read clock signal RCLK is high and stored in the latch formed by cross-coupled NOR gates 1860 and 1862. When read clock signal RCLK goes low, read amplifier 1800 turns off, but data remains stored in the latch formed by cross-coupled NOR gates 1860 and 1862. Inversion clock signals ICLK and ICLKB then go high and low, respectively, in response to the low level of read clock signal RCLK. These high and low levels of ICLK and ICLKB turn on CMOS pass gates 1864 and 1866, thereby applying an inverted state of the data bit to the input terminals of write amplifier 1804. Write amplifier 1804 is activated by write signal WCLK in synchronization with inversion clock signal ICLK and drives the inverted data bit back on local input-output signal lines 1840 and 1842, thereby rewriting inverted data back to the ferroelectric memory cell that originally produced the data bit. Address counter 1524 continues to produce the remaining sequence of array addresses until all data in memory array 1500 is inverted. When the address counter overflows and returns to an all-zero state, it propagates a carry signal CY from the most significant bit that resets the counter latch 1522, thereby terminating the data inversion cycle.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. For example, although a preferred embodiment of the present invention employs nonvolatile ferroelectric memory cells, the inventive concept of the present invention is equally applicable to any memory circuit having asymmetric data state degradation. In particular, dynamic random access memory cells may develop a net surface state charge in their storage capacitors due to prolonged data storage. This net surface state charge may lead to asymmetrical data state degradation as previously explained with respect to ferroelectric memory cells. Flash memory cells may also develop a preferential data storage state due to oxide wearout from repeated programming or prolonged data storage. Adverse effects of these and other phenomena may reduced by the present invention as will be understood by one of ordinary skill in the art having access to the instant specification.

Furthermore, the status latch 1526 (FIG. 15) may be used to store any nonvolatile data required by a semiconductor device. In particular, it may be used as a fuse replacement for memory redundancy, parameter storage for on-chip oscillators, or programmable logic switching. It is therefore intended that the appended claims encompass any such modifications or embodiments.

What is claimed is:

1. A method of storing data, comprising the steps of:
storing a datum in a memory cell;
receiving a control signal; and
inverting the datum in the nonvolatile memory cell in response to the control signal.

2. A method as in claim 1, wherein the memory cell is a nonvolatile memory cell.

3. A method as in claim 2, wherein the nonvolatile memory cell comprises Lead Zirconate Titanate (PZT).

4. A method as in claim 2, wherein the nonvolatile memory cell comprises Strontium Bismuth Titanate (SBT).

5. A method as in claim 1, wherein the control signal is an interrupt signal from a processor.

6. A method as in claim 1, wherein the control signal is a power up signal.

7. A method as in claim 4, wherein the power up signal is generated by a memory circuit including the memory cell.

8. A memory circuit, comprising:
a plurality of memory cells for storing data;
a control terminal arranged to receive a control signal;
a data circuit coupled to the control terminal and arranged to invert the data in the memory cells in response to the control signal.

9. A memory circuit as in claim 8, wherein the memory cells are nonvolatile memory cells.

10. A memory circuit as in claim 9, wherein the control signal is an interrupt signal from a processor.

11. A memory circuit as in claim 9, wherein the control signal is a power up signal.

12. A memory circuit as in claim 11, wherein the power up signal is generated by a memory circuit including the memory cell.

13. A nonvolatile latch circuit, comprising:
a first nonvolatile memory element arranged to store a first datum having a logic state;
a second nonvolatile memory element arranged to store a second datum having a logic state opposite the logic state of the first datum; and
a programming circuit arranged to invert the first datum and the second datum.

14. A nonvolatile latch circuit as in claim 13, comprising an amplifier circuit arranged to amplify a difference between the first datum and the second datum.

15. A nonvolatile latch circuit as in claim 13, wherein the nonvolatile memory elements are ferroelectric capacitors.

16. A nonvolatile latch circuit as in claim 13, wherein the first datum and the second datum represent a logic state of a memory array.

17. A nonvolatile latch circuit as in claim 13, wherein the first datum and the second datum represent an address of a defective memory cell a memory array.

18. A nonvolatile latch circuit as in claim 13, wherein the first datum and the second datum represent a parameter of an electrical circuit.
